(19) United States
(12) Patent Application Publication
(10) Pub. No.: US 2013/0062106 A1
(43) Pub. Date: Mar. 14, 2013

(54) Printed Circuit Board and Method of Manufacturing the Same

(71) Applicants: Jin Su Kim, Seoul (KR); Duk Nam Kim, Seoul (KR); Jae Hyun Ahn, Seoul (KR); Sang Myung Lee, Seoul (KR); Yeong Uk Seo, Seoul (KR); Chi Hee Ahn, Seoul (KR); Sung Woon Yoon, Seoul (KR); Myoung Hwa Nam, Seoul (KR)

(72) Inventors: Jin Su Kim, Seoul (KR); Duk Nam Kim, Seoul (KR); Jae Hyun Ahn, Seoul (KR); Sang Myung Lee, Seoul (KR); Yeong Uk Seo, Seoul (KR); Chi Hee Ahn, Seoul (KR); Sung Woon Yoon, Seoul (KR); Myoung Hwa Nam, Seoul (KR)

(73) Assignee: LG Innotek Co., Ltd., Seoul (KR)

(21) Appl. No.: 13/512,748

(22) PCT Filed: Nov. 26, 2010
(86) PCT No.: PCT/KR2010/008469

§ 371 Date: Nov. 30, 2012

(30) Foreign Application Priority Data
Nov. 30, 2009 (KR) 10-2009-0116883

(51) Int. Cl. H05K 3/10; H05K 1/09; H05K 1/11

(52) U.S. Cl. 174/257; 174/261; 29/846

(57) ABSTRACT

A structure of a printed circuit board and a method of manufacturing the same are provided. The manufacturing method includes a first step of forming at least one connecting bump on first circuit patterns and forming a first insulating layer to form an inner circuit board, a second step of processing a second insulating layer with a metal seed layer formed thereon using a mold to form second circuit patterns so as to construct an outer circuit board, and a third step of aligning the inner circuit board and the outer circuit board with each other and laminating the inner circuit board and the outer circuit board. Accordingly, a structure of a high-density high-reliability printed circuit board having a circuit embedded in an insulating layer can be provided. A seed layer forming process for forming an outmost circuit can be removed by using an insulating layer combined with a seed layer. In addition, a conductive structure in the form of a connecting bump is formed, and thus a complicated process of forming a via-hole and filling the via-hole with a conductive material is not required. Furthermore, a process of grinding the surface of the filled conductive material is removed so as to remarkably decrease a circuit error rate.

### TECHNICAL FIELD

The present invention relates to a printed circuit board having an embedded outer circuit pattern and a method of manufacturing the same.

### BACKGROUND ART

Techniques of embedding vias and patterns in insulating layers have been widely used to improve the reliability of a high-density pattern. There are two methods of manufacturing an embedded printed circuit board. The first method forms a circuit pattern first, embeds the circuit pattern in an insulating layer and removes a seed layer used to form the circuit pattern to obtain a final circuit. The second method manufactures a mold with a positive pattern corresponding to a circuit shape, forms a negative pattern in an insulating layer using the mold, fills the negative pattern with a conductive material and grinds the surface of the insulating layer to achieve a final circuit.

FIG. 1 illustrates the former method that forms a circuit pattern and embeds the circuit pattern in an insulating layer.

Specifically, a core layer 10 with a via-hole 14 and an inner circuit 12 is prepared (a), and two substrates each being manufactured by forming a circuit pattern 22 on a seed layer 20 with a carrier film 24 attached onto the backside thereof are provided (b). The two substrates are placed on both sides of the core layer 10 and pressed, and then the carrier film is removed (c). Regions at which via-holes will be formed are defined through DFR exposure (d) and portions of the seed layer 20 corresponding to the regions are selectively removed (e). Then, surface copper plating is performed on the removed portions of the seed layer 20 (f), and predetermined portions of the seed layer 20 is selectively removed using DFR to form via-holes 60 (g). The DRF is stripped off and solder paste is coated (h) to form a connecting via 52 and a connecting pad 62 (i).

This method has to manufacture the substrates with the circuit pattern 22 formed thereon in advance in order to form the embedded pattern, as described above, and thus the manufacturing process becomes complicated and productivity is decreased.

Referring to FIG. 2, an insulating layer 2 on which an insulating resin is deposited and a metal mold 1 are provided (a), and the metal mold 1 is pressed against the insulating layer 2 (b). Then, the metal mold is removed (c) and a via-hole 4 is formed in the insulating resin (d). A copper electroless plating layer 5 is formed on the insulating layer 2 (e) and a copper electroplating layer 6 is formed on the copper electroless plating layer 5 (f). The surface of the obtained structure is grounded to accomplish a printed circuit board.

However, this method requires a high-level technique to manufacture a negative pattern using the mold and fill the negative pattern with a conductive material. Accordingly, the manufacturing process is inefficient and takes a long time. Furthermore, surface grinding is indispensable, and thus circuit precision is decreased.

### DISCLOSURE OF INVENTION

### Technical Problem

It is an object of the present invention to provide a structure of a high-density high-reliability printed circuit board having a circuit embedded in an insulating layer and a manufacturing method for improving process efficiency and productivity by eliminating unnecessary processes.

### Solution to Problem

A method of manufacturing a printed circuit board comprises a first step of forming connecting bumps on first circuit patterns and forming a first insulating layer to form an inner circuit board; a second step of processing a second insulating layer with a metal seed layer formed thereon using a mold to form second circuit patterns so as to construct an outer circuit board; and a third step of aligning the inner circuit board and the outer circuit board with each other and laminating the inner circuit board and the outer circuit board.

The first step may comprise a step a1 of coating a photosensitive material on the first circuit patterns and forming connecting bump patterns; a step a2 of filling the connecting bump patterns with a metal material; and a step a3 of removing the photosensitive material and laminating the first insulating layer.

The metal material may comprise at least one of Cu, Ag, Sn, Au, Ni, and Pd.

The method may further comprise a hardening step after the step of filling the connecting bump patterns with the metal material.

The metal material may be filled using one of electroless plating, electroplating, screen printing, sputtering, evaporation, ink jetting and dispensing or a combination thereof.

The step a3 may form the first insulating layer such that the top faces of the connecting bumps are exposed from the surface of the first insulating layer.

The second step may comprise a step b1 of imprinting negative patterns on the second insulating layer with the metal seed layer formed thereon using a mold with positive patterns and a step b2 of filling the negative patterns of the second insulating layer with a metal material to form the second circuit patterns.

The step b1 further comprise a step of performing chemical or physical processing on the bottom of the negative patterns to expose the metal seed layer.

The step b2 may fill the negative patterns with at least one of Cu, Ag, Sn, Au, Ni and Pd using one of electroless plating, electroplating, screen printing, sputtering, evaporation, ink jetting and dispensing or a combination thereof.

The third step may laminate the inner circuit board and the outer circuit board through a press process using heat and pressure. The third step may laminate the inner circuit board and the outer circuit board with the first insulating layer and the second insulating layer being in a half hardened state.

The method may further comprise a step of removing the metal seed layer after the third step.

The second step may be performed before the first step or the first and second steps may be simultaneously performed. That is, the order of the step of forming the inner circuit board and the step of forming the outer circuit board may be changed.

A printed circuit board manufactured through the above manufacturing method comprises at least one connecting bump formed on first circuit patterns; a first insulating layer having the at least one connecting bump embedded therein and formed on the first circuit patterns; embedded second insulating patterns connected with the first circuit patterns through the at least one connecting bump; and a second insulating layer having the second circuit patterns embedded therein and laminated on the first insulating layer.

The thickness of the second circuit patterns may be less than the thickness of the second insulating layer. The first and second circuit patterns may be formed of one of Cu, Ag, Sn, Au, Ni, Pd.

According to the present invention, a structure of a high-density high-reliability printed circuit board having a circuit embedded in an insulating layer can be provided.

### Advantageous Effects of Invention

In a manufacturing method, a seed layer forming process for forming an outmost circuit can be removed by using an insulating layer combined with a seed layer. In addition, a conductive structure in the form of a connecting bump is formed, and thus a complicated process of forming a via-hole and filling the via-hole with a conductive material is not required. Furthermore, a process of grinding the surface of the filled conductive material is removed so as to remarkably decrease a circuit error rate.

### BRIEF DESCRIPTION OF DRAWINGS

FIGS. 1 and 2 illustrate conventional methods of manufacturing a printed circuit board; and

FIGS. 3, 4, 5 and 6 illustrate a method of manufacturing a printed circuit board according to the present invention.

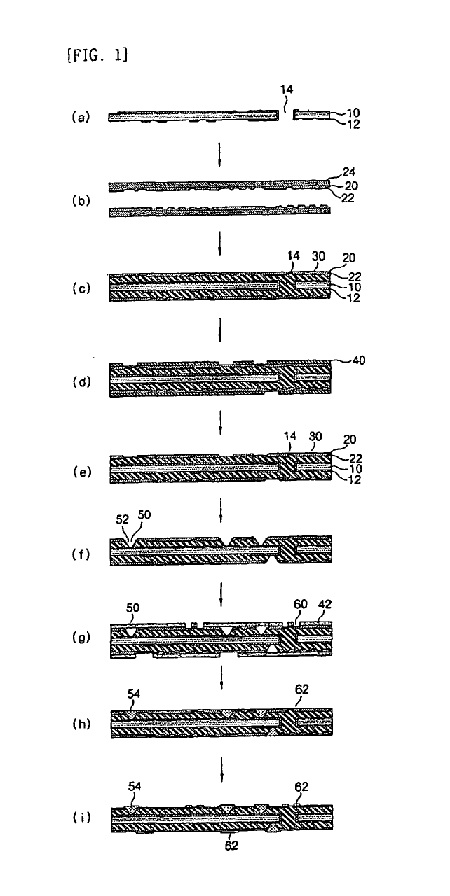

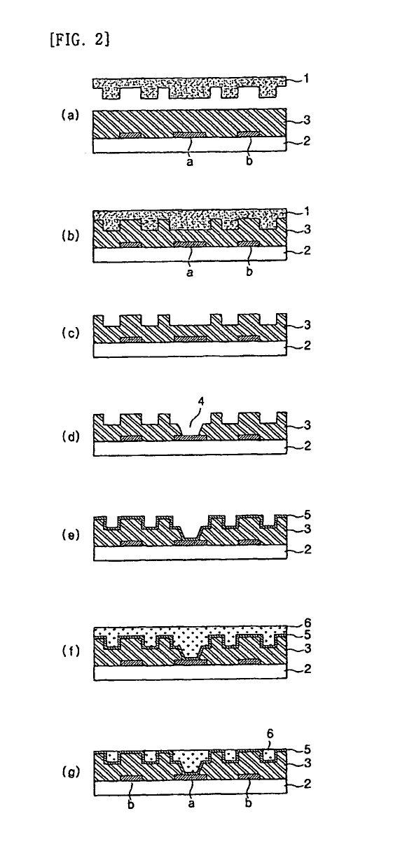

### BEST MODE FOR CARRYING OUT THE INVENTION

A method of manufacturing a printed circuit board according to the present invention includes a first step of forming connecting bumps on first circuit patterns and forming a first insulating layer to form an inner circuit board, a second step of processing a second insulating layer with a metal seed layer formed thereon using a mold to form second circuit patterns so as to construct an outer circuit board and a third step of aligning the inner circuit board and the outer circuit board with each other and laminating the inner circuit board and the outer circuit board.

### Mode for the Invention

The printed circuit board according to the present invention includes at least one connecting bump 130 formed on first circuit patterns 111. The at least one connecting bump 130 is embedded in the first insulating layer 140 formed on the first circuit patterns. The second insulating layer 210 is formed on the first insulating layer, and second circuit patterns 230 connected with the first circuit patterns through the connecting bump 130 is embedded in the second insulating layer.

The present invention will now be described more fully with reference to the accompanying drawings, in which exemplary embodiments of the invention are shown. Like reference numerals in the drawings like elements, and thus their description will be omitted. Though “First” and “Second” are used to explain various components, the components are not limited by the terms and the terms are used only to discriminate a component from another component.

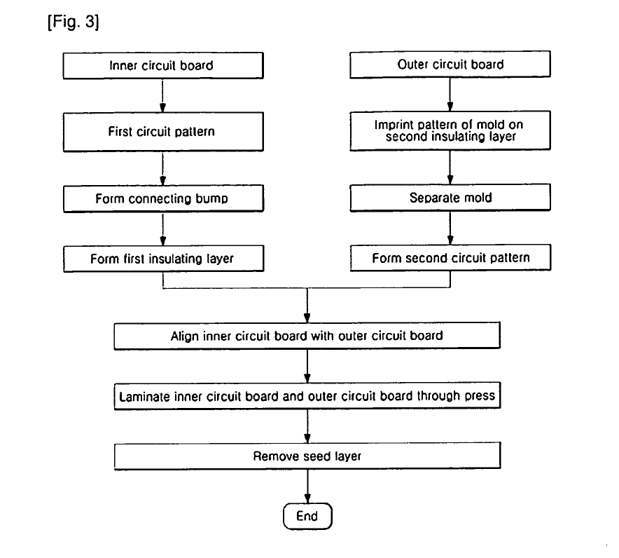

FIGS. 3, 4, 5 and 6 illustrate a method of manufacturing a printed circuit board according to the present invention.

The method of manufacturing a printed circuit board according to the present invention includes a first step of forming at least one connecting bump on first circuit patterns and forming a first insulating layer to form an inner circuit board, a second step of processing a second insulating layer with a seed layer formed thereon using a mold to form second circuit patterns to manufacture an outer circuit board, and a third step of aligning the inner circuit board and the outer circuit board with each other and laminating the inner circuit board and the outer circuit board.

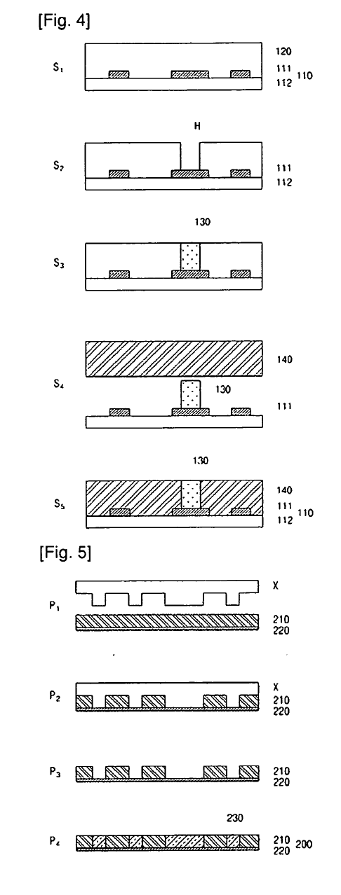

1. Step of forming inner circuit board (first step shown in FIG. 4)

In the first step of forming the inner circuit board, a photoresist layer 120 is formed on the inner circuit substrate 110 including a base substrate 111 and first circuit patterns 111 formed on the base substrate 112 in step S1. The photoresist layer 120 includes photosensitive materials to which photolithography can be applied. For example, dry film resist (DFR) may be used in the current embodiment.

Connecting bump patterns H are formed in the photoresist layer 120 using pho- tolithography performed through exposure, development and etching in step S2.

A metal material is filled in the connecting bump patterns H to form connecting bumps 130 in step S3. The metal material used to form the connecting bumps 130 may use metal paste formed of one of Cu, Ag, Sn, Au, Ni and Pd and may be filled in the connecting bump patterns H through one of electroless plating, electroplating, screen printing, sputtering, evaporation, ink jetting and dispensing or a combination of these methods.

A first insulating layer 140 is placed on the inner circuit board on which the connecting bumps 130 are formed, aligned with the inner circuit board and pressed in step S4. Here, step S4 may be performed such that the top faces of the connecting bumps 130 are exposed from the surface of the first insulating layer 140.

According to the above process, the inner circuit board according to the present invention can be obtained in step S5.

2. Step of forming outer circuit board (second step shown in FIG. 5)

The second step may be carried out before the first step. That is, the order of the step of forming the inner circuit board and the step of forming the outer circuit board may be changed.

Referring to FIG. 5, a base including a second insulating layer 210 and a metal seed layer 220 formed on one side of the second insulating layer 210 is prepared and a mold X with positive patterns is pressed against the base to imprint the positive patterns on the second insulating layer 210 so as to form negative patterns used to form second circuit patterns in steps P1 and P2. In this case, the thickness of the positive patterns of the mold X may be equal to or greater than the thickness of the second insulating layer 210. In addition, a step of performing chemical or physical processing on the bottom of the negative patterns to expose the metal seed layer 220 may be added. The metal seed layer 220 may be thinner than the second insulating layer 210.

The mold is separated in step P3 and the negative patterns are filled with a metal material to form the second circuit patterns 230 in step P4 so as to obtain the outer circuit board 200. Accordingly, the second circuit patterns 230 may be formed in thickness equal to or less than the thickness of the second insulating layer 210.

The negative patterns may be filled using metal paste made of one of Cu, Ag, Sn, Au, Ni and Pd. Furthermore, the negative patterns may be filled with one of Cu, Ag, Sn, Au, Ni and Pd through one of electroless plating, electroplating, screen printing, sputtering, evaporation, ink jetting and dispensing or a combination of these methods.

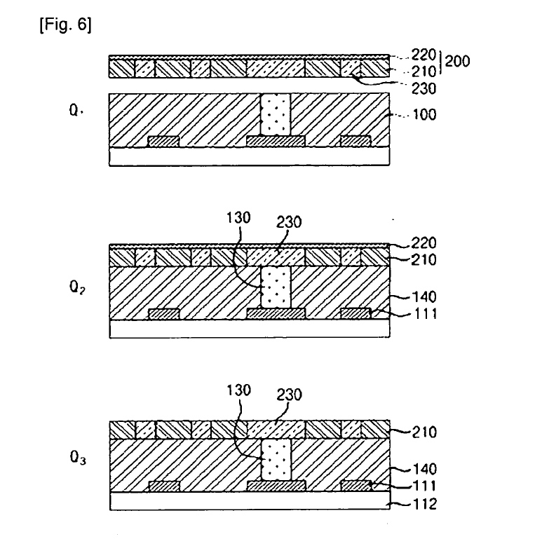

3. Aligning and laminating step (third step shown in FIG. 6)

The inner circuit board 100 and the outer circuit board 200 formed through the above manufacturing processes are aligned and laminated.

Specifically, the second circuit patterns 230 is aligned with the first insulating layer 140 with the surface of the metal seed layer 220 facing the outside in step Q1 shown in FIG. 6. Then, the inner circuit board 100 and the outer circuit board 200 are attached to each other through a method such as press using heat and pressure in step Q2. In this case, the inner circuit board 100 and the outer circuit board 200 may be laminated with the first and second insulating layers being in a half hardened state to improve attachment efficiency.

A step of removing the metal seed layer (step Q3) may be performed after the third step.

The printed circuit board manufactured through the above manufacturing method may have the following structure. The structure of the printed circuit board will now be explained with reference to FIG. 6.

The printed circuit board includes the connecting bumps 130 formed on the first circuit patterns 111. The connecting bumps 130 are embedded in the first insulating layer 140 formed on the first circuit patterns 111.

The second insulating layer 210 is formed on the first insulating layer 140. The embedded second circuit patterns 230 connected to the first circuit patterns 111 through the connecting bumps 130 are formed in the second insulating layer 210.

That is, the connecting bumps 130 connected to the bottom of the second circuit patterns 230 penetrate the first insulating layer 140 to be connected to the first circuit patterns 111. The second circuit patterns 230 are embedded in the second insulating layer 210.

The printed circuit board having the above structure has a circuit embedded in an insulating layer, and thus the density and reliability of the printed circuit board can be improved. Furthermore, an unnecessary process that takes a long time is eliminated from the manufacturing method according to the present invention so as to improve process efficiency and remarkably decrease a circuit error rate.

While the present invention has been particularly shown in and described with reference to exemplary embodiments thereof, it will be understood by those of ordinary skill in the art that various changes in form and details may be made therein without departing the spirit and scope of the present invention as defined by the following claims.

1. A method of manufacturing a printed circuit board, comprising:
a first step of forming connecting bumps on first circuit patterns and forming a first insulating layer to form an inner circuit board;
a second step of processing a second insulating layer with a metal seed layer formed thereon using a mold to form second circuit patterns so as to construct an outer circuit board; and
a third step of aligning the inner circuit board and the outer circuit board with each other and laminating the inner circuit board and the outer circuit board.

2. The method of claim 1, wherein the first step comprises:
a step a1 of coating a photosensitive material on the first circuit patterns and forming connecting bump patterns;
a step a2 of filling the connecting bump patterns with a metal material; and
a step a3 of removing the photosensitive material and laminating the first insulating layer.

3. The method of claim 2, wherein the metal material comprises at least one of Cu, Ag, Sn, Au, Ni, and Pd.

4. The method of claim 2, further comprising a hardening step after the step of filling the connecting bump patterns with the metal material.

5. The method of claim 2, wherein the step a2 fills the metal material using one of electroless plating, electroplating, screen printing, sputtering, evaporation, ink jetting and dispensing or a combination thereof.

6. The method of claim 2, wherein the step a3 forms the first insulating layer such that the top faces of the connecting bumps are exposed from the surface of the first insulating layer.

7. The method of claim 1, wherein the second step comprises:
a step b1 of imprinting negative patterns on the second insulating layer with the metal seed layer formed thereon using a mold with positive patterns; and
a step b2 of filling the negative patterns of the second insulating layer with a metal material to form the second circuit patterns.

8. The method of claim 7, further comprising a step of performing chemical or physical processing on the bottom of the negative patterns to expose the metal seed layer.

9. The method of claim 7, wherein the step b2 fills the negative patterns with at least one of Cu, Ag, Sn, Au, Ni and Pd using one of electroless plating, electroplating, screen printing, sputtering, evaporation, ink jetting and dispensing or a combination thereof.

10. The method of claim 7, wherein the third step laminates the inner circuit board and the outer circuit board through a press process using heat and pressure.

11. The method of claim 10, wherein the third step laminates the inner circuit board and the outer circuit board with the first insulating layer and the second insulating layer being in a half hardened state.

12. The method of claim 7, further comprising a step of removing the metal seed layer after the third step.

13. The method of claim 7, wherein the second step is performed before the first step or the first and second steps are simultaneously performed.

14. A printed circuit board comprising:
at least one connecting bump formed on first circuit patterns;
a first insulating layer having the at least one connecting bump embedded therein and formed on the first circuit patterns;
embedded second insulating patterns connected with the first circuit patterns through the at least one connecting bump; and
a second insulating layer having the second circuit patterns embedded therein and laminated on the first insulating layer.

15. The printed circuit board of claim 14, wherein the thickness of the second circuit patterns is less than the thickness of the second insulating layer.

16. The printed circuit board of claim 15, wherein the first and second circuit patterns are formed of one of Cu, Ag, Sn, Au, Ni, Pd.
